(19) United States
(12) Patent Application Publication
(10) Pub. No.: US 2009/0126914 A1
(43) Pub. Date: May 21, 2009

(54) Isolated Gas Cooling System for Cooling Electrical Components of an Electronic Display

(75) Inventor: William DUNN, Alpharetta, GA (US)

Correspondence Address: STANDLEY LAW GROUP LLP, 6300 Riverside Drive, Dublin, OH, 43017, US

(73) Assignee: MANUFACTURING RESOURCES INTERNATIONAL, INC., Alpharetta, GA (US)

(21) Appl. No.: 12/234,360

(22) Filed: Sep. 19, 2008

Related U.S. Application Data
(63) Continuation-in-part of application No. 11/941,728, filed on Nov. 16, 2007.
Application No. 11/941,728 is a continuation-in-part of application No. 12/191,384, filed on Aug. 14, 2008.
Application No. 12/191,384 is a continuation-in-part of application No. 12/234,307, filed on Sep. 19, 2008.
(60) Provisional application No. 61/053,713, filed on May 16, 2008.
(60) Provisional application No. 61/057,599, filed on May 30, 2008.
(60) Provisional application No. 61/039,454, filed on Mar. 26, 2008.
(60) Provisional application No. 61/076,126, filed on Jun. 26, 2008.

(51) Int. Cl. F28D 15/00; G05D 23/00; H05K 7/20

(52) U.S. Cl. 165/121; 165/287; 361/695

(57) ABSTRACT

A preferred embodiment relates to a cooling system and a method for cooling an electronic display and its electronic components. An exemplary embodiment includes a transparent gas cooling chamber. The electronic components which operate the system are preferably housed both within the electronic display housing and within the cooling chamber. The cooling system defines a gas compartment that is anterior and posterior to the electronic display surface. Fans may be used to propel the isolated gas through the cooling system. The circulating gas removes heat directly from the electronic display surface as well as the electronic components which operate the display. The isolated gas is transparent or at least semi-transparent. The image quality of an exemplary embodiment remains essentially unchanged, even though the gas is flowing through a narrow channel over the visible face of the electronic display surface.

### CROSS-REFERENCE TO RELATED APPLICATIONS

This application is a non-provisional patent application and claims priority to U.S. Provisional Application No. 61/053,713 filed May 16, 2008; 61/039,454 filed Mar. 26, 2008; 61/057,599 filed May 30, 2008; and 61/076,126 filed Jun. 26, 2008, which are hereby incorporated by reference in their entirety. This application is also a continuation in part of U.S. patent application Ser. No. 11/941,728 filed Nov. 16, 2007, which is hereby incorporated by reference in its entirety. This application is also a continuation in part of U.S. patent application Ser. No. 12/191,834 filed Aug. 14, 2008, which is hereby incorporated by reference in its entirety. This application is also a continuation in part of U.S. patent application Ser. No. 12/234,307 filed Sep. 19, 2008, which is hereby incorporated by reference in its entirety.

### TECHNICAL FIELD

Exemplary embodiments generally relate to cooling systems and in particular to cooling systems for cooling electronic displays and their electronic components.

### BACKGROUND OF THE ART

Conductive and convective heat transfer systems for electronic displays are known. These systems of the past generally attempt to remove heat from the electronic components in a display through as many sidewalls of the display as possible. In order to do this, the systems of the past have relied primarily on fans for moving air past the components to be cooled and out of the display. In some cases, the heated air is moved into convectively thermal communication with fins. Some of the past systems also utilize conductive heat transfer from heat producing components directly to heat conductive housings for the electronics. In these cases, the housings have a large surface area, which is in convective communication with ambient air outside the housings. Thus, heat is transferred convectively or conductively to the housing and is then transferred into the ambient air from the housing by natural convection.

While such heat transfer systems have enjoyed a measure of success in the past, improvements to displays require even greater cooling capabilities.

### SUMMARY OF THE EXEMPLARY EMBODIMENTS

In particular, cooling devices for electronic displays of the past have generally used convective heat dissipation systems that function to cool an entire interior of the display by one or more fans and fins, for example. By itself, this is not adequate in many climates, especially when radiative heat transfer from the sun through a display window becomes a major factor. In many applications and locations 200 Watts or more of power through such a display window is common. Furthermore, the market is demanding larger screen sizes for displays. With increased electronic display screen size and corresponding display window size more heat will be generated and more heat will be transmitted into the displays.

In the past, many displays have functioned satisfactorily with ten or twelve inch screens. Now, many displays are in need of screens having sizes greater than or equal to twenty-four inches that may require improved cooling systems. For example, some outdoor applications call for forty-seven inch screens and above. With increased heat production with the larger screens and radiative heat transfer from the sun through the display window, heat dissipation systems of the past, which attempt to cool the entire interior of the display with fins and fans, are no longer adequate.

A large fluctuation in temperature is common in the devices of the past. Such temperature fluctuation adversely affects the electronic components in these devices. Whereas the systems of the past attempted to remove heat only through the non-display sides and rear components of the enclosure surrounding the electronic display components, a preferred embodiment causes heat transfer from the face of the display as well. By the aspects described below, embodiments have made consistent cooling possible for electronic displays having screens of sizes greater than or equal to twelve inches. For example, cooling of a 55 inch screen can be achieved, even in extremely hot climates. Greater cooling capabilities are provided by the device and method described and shown in more detail below.

An exemplary embodiment relates to an isolated gas cooling system and a method for cooling the electronic components of an electronic display. An exemplary embodiment includes an isolated gas cooling chamber. The gas cooling chamber is preferably a closed loop which includes a first gas chamber comprising a transparent anterior plate and a second gas chamber comprising a cooling plenum. The first gas chamber is anterior to and coextensive with the viewable face of the electronic display surface. The transparent anterior plate may be set forward of the electronic display surface by spacers defining the depth of the first gas chamber. A cooling chamber fan, or equivalent means, may be located within the cooling plenum. The fan may be used to propel gas around the isolated gas cooling chamber loop. As the gas traverses the first gas chamber it contacts the electronic display surface, absorbing heat from the surface of the display. Because the gas and the relevant surfaces of the first gas chamber are transparent, the image quality remains excellent. After the gas has traversed the transparent first gas chamber, the gas may be directed into the rear cooling plenum. Located within the rear cooling plenum can be any number of electronic components which may be used to run the display. These components may include but are not limited to: transformers, circuit boards, resistors, capacitors, batteries, power transformers, motors, illumination devices, wiring and wiring harnesses, and switches.

In order to cool the gas in the plenum, external convective or conductive means may be employed. In at least one embodiment, an external fan unit may be utilized to blow cool air over the exterior surfaces of the plenum. The heat from the warm gas may radiate into the walls of the plenum and then escape the walls of the plenum by convection or conduction or a combination of both. The external fan unit may be positioned at the base of the housing for the entire display. Once the air is heated by flowing over the exterior surfaces of the plenum, the heated air may exit the housing as exhaust. Note, that the air from this external fan should not enter the isolated cooling system as this would introduce dust and contaminates into the otherwise clean air.

The foregoing and other features and advantages will be apparent from the following more detailed description of the particular embodiments, as illustrated in the accompanying drawings.

### BRIEF DESCRIPTION OF THE DRAWINGS

A better understanding of an exemplary embodiment will be obtained from a reading of the following detailed description and the accompanying drawings wherein identical reference characters refer to identical parts and in which:

FIG. 1 is a perspective view of an exemplary embodiment in conjunction with an exemplary electronic display.

FIG. 2 is an exploded perspective view of an exemplary embodiment showing components of the isolated gas cooling system.

FIG. 3 is top plan view of an exemplary embodiment of the cooling chamber.

FIG. 4 is a front perspective view of an embodiment of the isolated cooling chamber, particularly the transparent anterior surface of first gas chamber.

FIG. 5 is a rear perspective view of an embodiment of the isolated cooling chamber, particularly the cooling plenum.

FIG. 6 is a rear perspective view of an embodiment of the isolated cooling chamber showing surface features that may be included on the plenum

FIG. 7 is a top plan view of an exemplary embodiment of the cooling chamber showing surface features that may be included on the plenum.

FIG. 8 is a front perspective view of an embodiment of the isolated cooling chamber with included thermoelectric modules.

FIG. 9 is a top plan view of an exemplary embodiment of the cooling chamber with included thermoelectric modules.

FIG. 10 is an exploded perspective view of an exemplary embodiment showing components of the isolated gas cooling system.

### DETAILED DESCRIPTION

Embodiments relate to a cooling system for the electronic components of an electronic display and to combinations of the cooling system and the electronic display. Exemplary embodiments provide an isolated gas cooling system for an electronic display. Such an isolated gas cooling system is the subject matter of co-pending U.S. Application No. 61/033,064, incorporated by reference herein.

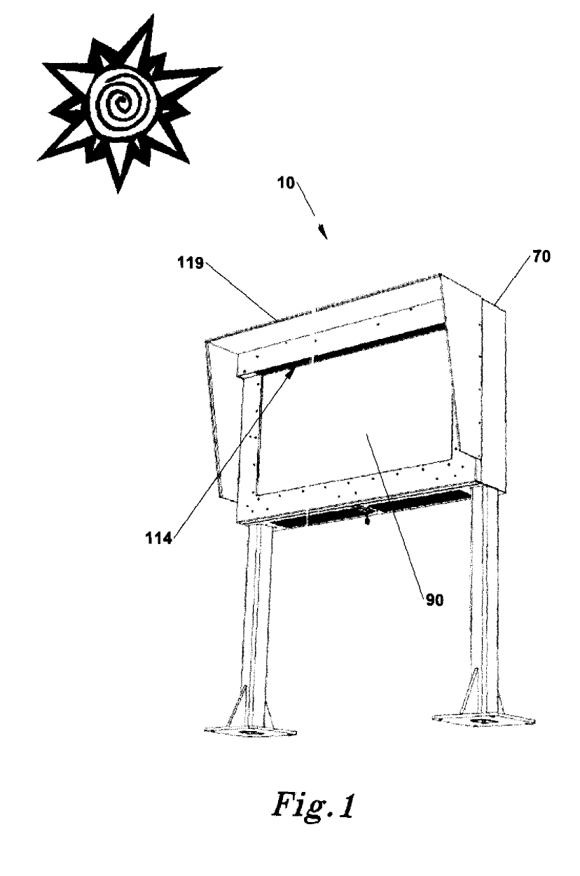

As shown in FIG. 1, when the display 10 is exposed to outdoor elements, the temperatures inside the display 10 will vary greatly without some kind of cooling device. As such, the electronics including the display screen (e.g., LCD screen) will have a greatly reduced life span. By implementing certain embodiments of the cooling system disclosed herein, temperature fluctuation is greatly reduced. This cooling capability has been achieved in spite of the fact that larger screens generate more heat than smaller screens.

The display shown is equipped with an innovative gas cooling system. Accordingly, it may be placed in direct sunlight. Although the cooling system may be used on smaller displays, it is especially useful for larger LCD, LED, or organic light emitting diodes (OLED) displays. These screens, especially with displays over 24 inches, face significant thermoregulatory issues in outdoor environments.

In FIG. 1, the display area of the electronic display shown includes a narrow gas chamber that is anterior to and coextensive with the electronic display surface. The display shown also is equipped with an optional air curtain device 114 which is the subject matter of co-pending U.S. application Ser. No. 11/941,728, incorporated by reference herein. Optionally, the display also has a reflection shield 119, to mitigate reflection of the sunlight on the display surface. Additionally, in outdoor environments, housing 70 is preferably a color which reflects sunlight.

It is to be understood that the spirit and scope of the disclosed embodiments includes cooling of displays including, but not limited to LCDs. By way of example and not by way of limitation, exemplary embodiments may be used in conjunction with displays selected from among LCD (including TFT or STN type), light emitting diode (LED), organic light emitting diode (OLED), field emitting display (FED), cathode ray tube (CRT), and plasma displays. Furthermore, embodiments may be used with displays of other types including those not yet discovered. In particular, it is contemplated that the system may be well suited for use with full color, flat panel OLED displays. While the embodiments described herein are well suited for outdoor environments, they may also be appropriate for indoor applications (e.g., factory environments) where thermal stability of the display may be at risk.

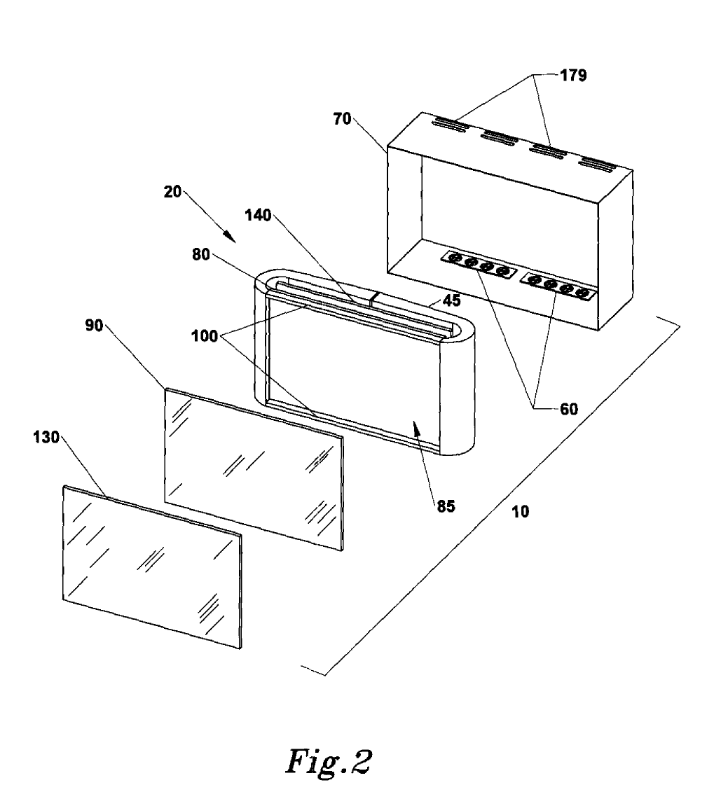

As shown in FIG. 2 an exemplary embodiment 10 of the electronic display and gas cooling system includes an isolated gas cooling chamber 20 contained within an electronic display housing 70. A narrow transparent first gas chamber is defined by spacers 100 and transparent front plate 90. A second transparent front plate 130 may be laminated to front plate 90 to help prevent breakage of front glass 90. As shown in FIG. 2, cooling chamber 20 may surround LCD stack 80 and associated backlight panel 140.

The gas cooling system 10 shown in FIG. 2 may include means for cooling gas contained within the second gas chamber. These means may include a fan 60 which may be positioned at the base of the display housing 70. The fan will force the cooler ingested air over the exterior surfaces of a posterior cooling plenum 45. If desired, an air conditioner (not shown) may also be utilized to cool the air which contacts the external surfaces of plenum 45.

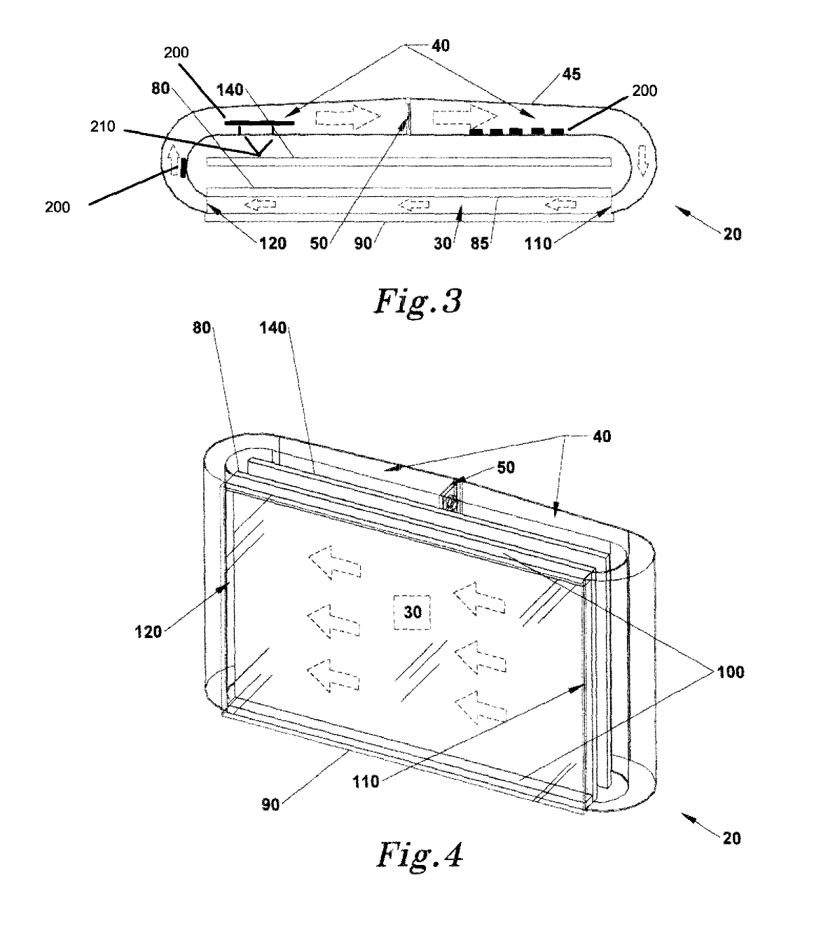

Referring to FIG. 3, in at least one embodiment the isolated gas cooling chamber 20 comprises a closed loop which includes a first gas chamber 30 (see FIG. 3) and a second gas chamber 40. The first gas chamber includes a transparent plate 90. The second gas chamber comprises a cooling plenum 45. The term “isolated gas” refers to the fact that the gas within the isolated gas cooling chamber 20 is essentially isolated from external air in the housing of the display. Because the first gas chamber 30 is positioned in front of the display image, the gas should be substantially free of dust or other contaminates that might negatively affect the display image.

Various electronic components 200 are shown in various positions throughout the plenum 45. Placing these components 200 within the plenum allows for increased air flow around the components 200 and increased cooling. Further, location of the components 200 within the plenum 45 can help satisfy space considerations, as well as manufacturing and repair considerations. These components 200 may be mounted directly on the walls or surfaces of the plenum 45, or may be suspended by rods or posts 210. The precise mounting of the components 200 can vary depending on the amount of cooling that is required for the component, manufacturing limitations, wire routing benefits, or ease of repair or replacement of the specific component. Further, the precise wiring of the components 200 can vary depending on similar factors. The wiring may pass through a single hole in the plenum 45 and then spread to each component or there may be various holes in the plenum 45 to accommodate the wiring for each component individually. In a further embodiment, PCB boards and other typical electronic mounting surfaces may be integrated into the plenum 45 such that the mounting board itself substitutes as a portion of the plenum wall.

The isolated gas may be almost any transparent gas, for example, normal air, nitrogen, helium, or any other transparent gas. The gas is preferably colorless so as not to affect the image quality. Furthermore, the isolated gas cooling chamber need not necessarily be hermetically sealed from the external air. It is sufficient that the gas in the chamber is isolated to the extent that dust and contaminates may not substantially enter the first gas chamber.

In the closed loop configuration shown in FIG. 3, the first gas chamber 30 is in gaseous communication with the second gas chamber 40. A cooling chamber fan 50 may be provided within the posterior plenum 45. The cooling fan 50 may be utilized to propel gas around the isolated gas cooling chamber 20. The first gas chamber 30 includes at least one front glass 90 mounted in front of an electronic display surface 85. The front glass 90 may be set forward from the electronic display surface 85 by spacers 100 (see FIG. 4). The spacing members 100 define the depth of the narrow channel passing in front of the electronic display surface 85. The spacing members 100 may be independent or alternatively may be integral with some other component of the device (e.g., integral with the front plate). The electronic display surface 85, the spacing members, and the transparent front plate 90 define a narrow first gas chamber 30. The chamber 30 is in gaseous communication with plenum 45 through entrance opening 110 and exit opening 120.

As shown in FIG. 3, a posterior surface of the first gas chamber 30 preferably comprises the electronic display surface 85 of the display stack 80. As the isolated gas in the first gas chamber 30 traverses the display it contacts the electronic display surface 85. Contacting the cooling gas directly to the electronic display surface 85 enhances the convective heat transfer away from the electronic display surface 85.

Advantageously, in exemplary embodiments the electronic display surface 85 comprises the posterior surface of the first gas chamber 30. Accordingly, the term “electronic display surface” refers to the front surface of a typical electronic display (in the absence of the embodiments disclosed herein). The term “viewable surface” or “viewing surface” refers to that portion of the electronic display surface from which the electronic display images may be viewed by the user.

The electronic display surface 85 of typical displays is glass. However, neither display surface 85, nor transparent front plate 90, nor optional second transparent front plate 130 need necessarily be glass. Therefore, the term “glass” will be used herein interchangeably with the term plate. By utilizing the electronic display surface 85 as the posterior surface wall of the gas compartment 30, there may be fewer surfaces to impact the visible light traveling through the display. Furthermore, the device will be lighter and cheaper to manufacturer.

Although the embodiment shown utilizes the electronic display surface 85, certain modifications and/or coatings (e.g., anti-reflective coatings) may be added to the electronic display surface 85, or to other components of the system in order to accommodate the coolant gas or to improve the optical performance of the device. In the embodiment shown, the electronic display surface 85 may be the front glass plate of a liquid crystal display (LCD) stack. However, almost any display surface may be suitable for embodiments of the present cooling system. Although not required, it is preferable to allow the cooling gas in the first gas chamber 30 to contact the electronic display surface 85 directly. In this way, the convective effect of the circulating gas will be maximized. Preferably the gas, which has absorbed heat from the electronic display surface 85 may then be diverted to the cooling plenum 45 where the collected heat energy in the gas may be dissipated into the air within the display housing 70 by conductive and or convective means.

To prevent breakage, the optional second surface glass 130 may be adhered to the front surface of glass 90. Alternatively surface glass 90 may be heat tempered to improve its strength. As shown in FIG. 3, fan 50 propels a current of air around the loop (see arrows) of the isolated gas cooling chamber 20. The plenum 45 defining the second gas chamber 40 is adapted to circulate the gas behind the electronic display surface 85. The plenum 45 preferably surrounds most of the heat generating components of the electronic display, for example, backlight panel 140 (e.g., an LED backlight).

FIG. 4 shows that the anterior surface 90 of the first gas chamber 30 is transparent and is positioned anterior to and at least coextensive with a viewable area of an electronic display surface 85. The arrows shown represent the movement of the isolated gas through the first gas chamber 30. As shown, the isolated gas traverses the first gas chamber 30 in a horizontal direction. Although cooling system 20 may be designed to move the gas in either a horizontal or a vertical direction, it is preferable to propel the gas in a horizontal direction. In this way, if dust or contaminates do enter the first gas chamber 30, they will tend to fall to the bottom of chamber 30 outside of the viewable area of the display. The system may move air left to right, or alternatively, right to left.

As is clear from FIG. 4, to maximize the cooling capability of the system, the first gas chamber 30 preferably covers the entire viewable surface of the electronic display surface 85. Because the relevant surfaces of the first gas chamber 30 as well as the gas contained therein are transparent, the image quality of the display remains excellent. Anti-reflective coatings may be utilized to minimize specular and diffuse reflectance. After the gas traverses the first gas chamber 30 it exits through exit opening 120. Exit opening 120 defines the entrance junction into the rear cooling plenum 45.

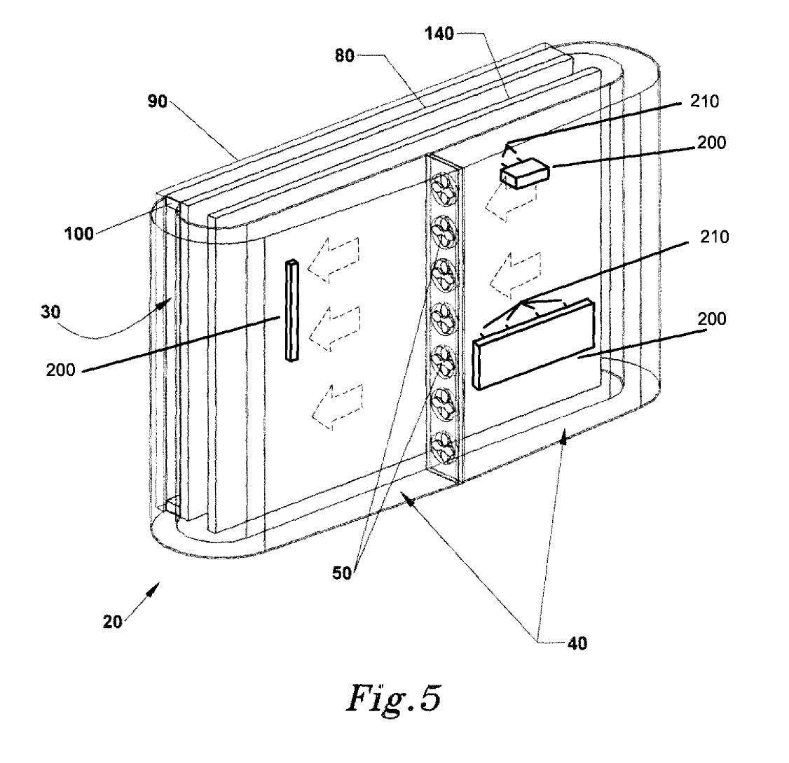

FIG. 5 shows a schematic of the rear cooling plenum 45 (illustrated as transparent for explanation). One or more fans 50 within the plenum may provide the force necessary to move the isolated gas through the isolated gas cooling chamber. Various electronic components 200 can be located anywhere throughout the second gas chamber 40. Again, these components can be mounted directly on the walls of the chamber or supported on rods or posts 210. Thus, the cooling plenum 45 can be designed to not only take heat from the first gas chamber 30 but also to take heat from these various electronic components 200. Plenum 45 may have various contours and features to accommodate the internal structures within a given electronic display application.

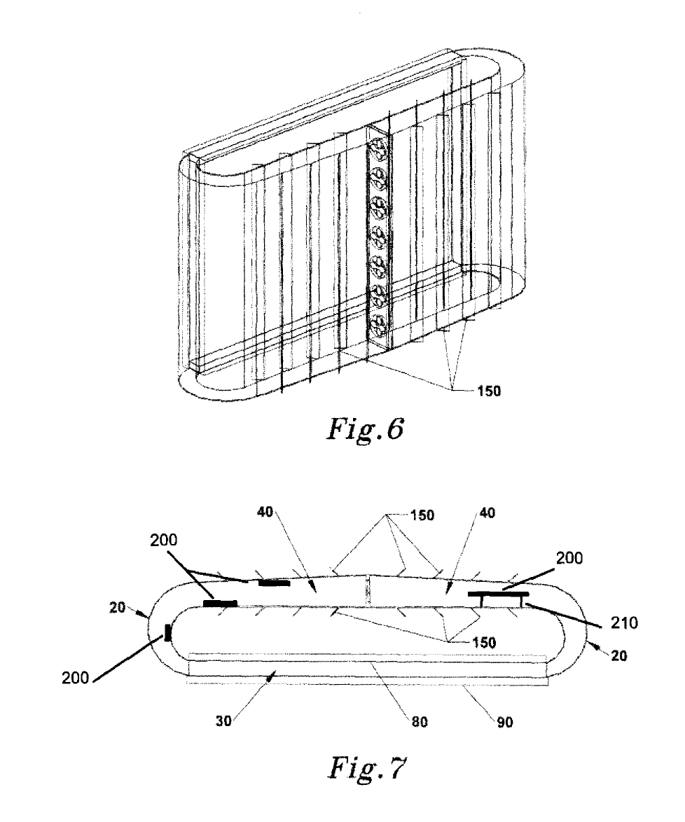

As can be discerned in FIGS. 6 and 7, various surface features 150 may be added to improve heat dissipation from the plenum 45. These surface features 150 provide more surface area to radiate heat away from the gas within the second gas chamber 40. These features 150 may be positioned at numerous locations on the surfaces of the plenum 45. These features may be used to further facilitate the cooling of various electronic components 200 which may also be located within the plenum 45.

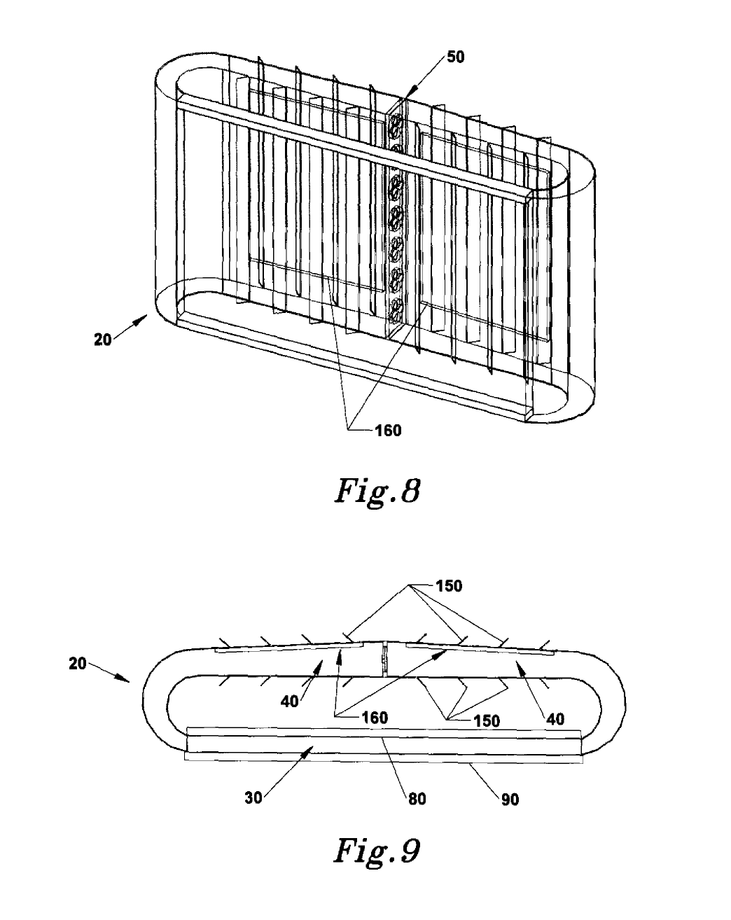

Referring to FIGS. 8 and 9, one or more thermoelectric modules 160 may be positioned on at least one surface of the plenum 45 to further cool the gas contained in the second gas chamber 40. The thermoelectric modules 160 may be used independently or in conjunction with surface features 150. Alternatively, thermoelectric modules 160 may be useful to heat the gas in the rear plenum if the unit is operated in extreme cold conditions. Thermoelectric modules 160 may also be used to further facilitate the cooling or heating of various electronic components 200 which may also be located within the plenum 45.

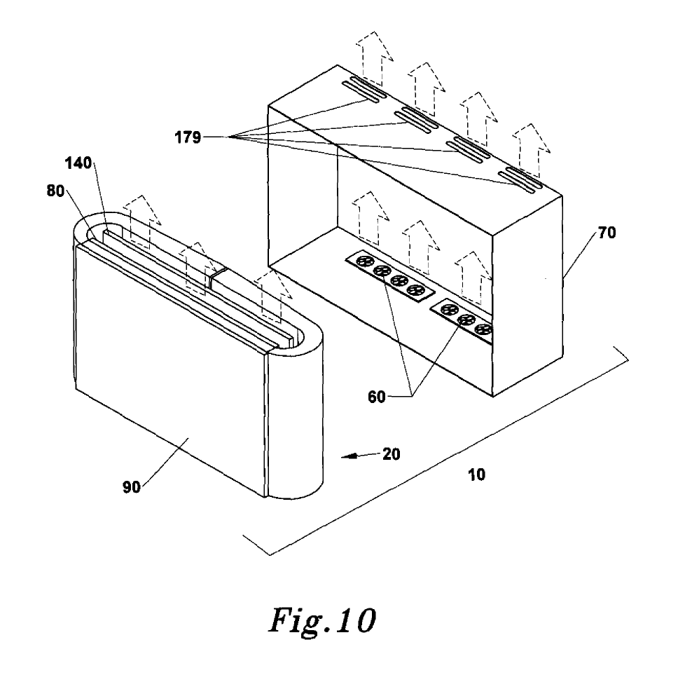

FIG. 10 shows an exemplary method for removing heat in the gas contained in the rear plenum 45. Fan 60 may be positioned to ingest external air and blow that air into the display housing 70. Preferably, the air will contact the anterior and posterior surfaces of the plenum 45. Furthermore, in this configuration, fan 60 will also force fresh air past the heat generating components of the electronic display (e.g., the TFT layer, backlight, transformers, circuit boards, resistors, capacitors, batteries, power transformers, motors, illumination devices, wiring and wiring harnesses, and switches) to further improve the cooling capability of the cooling system. The heated exhaust air may exit through one or more apertures 179 located on the display housing 70. In a preferred embodiment, the air from this external fan 60 should not enter the isolated cooling system as this would introduce dust and contaminates into the otherwise clean gas.

Besides thermoelectric modules 160, there are a number of ways to cool the gas in the second gas chamber. For example air conditioners or other cooling means known by those skilled in the art may be useful for cooling the gas contained in plenum 45.

While the display is operational, the isolated gas cooling system may run continuously. However, if desired, a temperature sensor (not shown) and a switch (not shown) may be incorporated within the electronic display 10. The thermostat may be used to detect when temperatures have reached a predetermined threshold value. In such a case, the isolated gas cooling system may be selectively engaged when the temperature in the display reaches a predetermined value. Predetermined thresholds may be selected and the system may be configured with a thermostat (not shown) to advantageously keep the display within an acceptable temperature range.

An optional air filter (not shown) may be employed within the plenum to assist in preventing contaminates and dust from entering the first gas chamber 30.

Having shown and described preferred embodiments, those skilled in the art will realize that many variations and modifications may be made to affect the embodiments and still be within the scope of the claimed invention. Additionally, many of the elements indicated above may be altered or replaced by different elements which will provide the same result and fall within the spirit of the exemplary embodiments. It is the intention, therefore, to limit the invention only as indicated by the scope of the claims.

1. A gas cooling system for an electronic display having a display surface, the system comprising:
a first gas chamber positioned anterior to the electronic display surface;
a second gas chamber in gaseous communication with said first gas chamber and adapted to cool gas;
a cooling chamber fan within said second gas chamber to propel gas around the first and second gas chambers;
one or more electronic components within said second gas chamber and positioned so that propelled gas contacts one or more surfaces of the components; and
means for cooling the gas contained within the second gas chamber.

2. The system of claim 1, wherein:
the first gas chamber comprises a transparent anterior plate; and
the second gas chamber comprises a cooling plenum.

3. The system of claim 2, wherein the first gas chamber further comprises the electronic display surface;
spacers separating the electronic display surface and said transparent anterior plate; and
an entrance opening and an exit opening.

4. The system of claim 1 wherein:
said one or more electronic components are mounted on the surfaces of said second chamber

5. The system of claim 1 wherein:
said one or more electronic components are mounted on posts which suspend said one or more components from the surfaces of said second chamber.

6. The system of claim 1, wherein said one or more electronic components comprise any one of the following: transformers, circuit boards, resistors, capacitors, batteries, power transformers, motors, illumination devices, wiring and wiring harnesses, and switches.

7. The system of claim 1, wherein:
the fan runs continuously when the electronic display is operating.

8. The system of claim 1, further comprising:
a temperature sensing device within said first or second gas chamber;
a switch in communication with said temperature sensing device and said fan; and
wherein the fan is switched on when the temperature reaches a threshold value.

9. The system of claim 2 further comprising:
surface features within said plenum to facilitate the transfer of heat away from the gas.

10. The system of claim 2 further comprising
one or more thermoelectric modules within said plenum.

11. The system of claim 1 further comprising
a filter within the second gas chamber.

12. The system of claim 2, wherein:
the means for cooling the gas contained within the second gas chamber comprises a fan adapted to force air over the external surfaces of the plenum.

13. The system of claim 2 wherein the cooling plenum is adapted to transfer heat from said electronic components to the isolated gas.

14. The system of claim 12 further comprising:
an air curtain device to direct air across the external surface of the first gas chamber.

15. A thermally regulated electronic display comprising:
an electronic display having a display surface;
a first gas chamber positioned anterior to the display surface of the electronic display and adapted to transfer heat from the display surface to a gas;
a second gas chamber in gaseous communication with said first gas chamber, said second gas chamber comprising
a cooling plenum;
a cooling chamber fan within said cooling plenum to propel gas around the first and second gas chambers; and
one or more electronic components within said cooling plenum, said components being operatively connected to said electronic display and positioned so that propelled gas contacts one or more surfaces of the components; and
means for cooling the gas contained within the cooling plenum.

16. The system of claim 15, wherein said one or more electronic components comprise any one of the following: transformers, circuit boards, resistors, capacitors, batteries, power transformers, motors, illumination devices, wiring and wiring harnesses, and switches.

17. The display from claim 15 further wherein the means for cooling the gas contained within the cooling plenum comprises any one of the following:
a fan adapted to force air over the external surfaces of the plenum;
surface features on said cooling plenum;
one or more thermoelectric modules on said cooling plenum; and
an air conditioning device operatively connected to said second chamber.

18. A method for cooling an electronic display having a display surface with isolated gas, comprising the steps of:
providing an isolated gas system comprising a first gas chamber which is in contact with the electronic display surface and a second gas chamber comprising a cooling plenum, electronic components, and a fan, wherein the first and second gas chambers are in gaseous communication;
forcing isolated gas into the first gas chamber;
transferring heat from the electronic display surface to the isolated gas;
directing the isolated gas into the cooling plenum;
transferring heat from the electronic components to the isolated gas;
cooling the isolated gas in the plenum; and
reintroducing the cooled isolated gas into the first gas chamber.

19. The method of claim 17, wherein the cooling step comprises the steps of:
transferring heat from the isolated gas to the walls of the cooling plenum;
forcing air over the external surfaces of the plenum; and
transferring heat from the walls of the cooling plenum to the air.

20. The method of claim 17, wherein the step of transferring heat from the electronic components to the isolated gas is performed by forcing the isolated gas over one or more surfaces of the electronic components.
